(19) United States
(12) Patent Application Publication
(10) Pub. No.: US 2025/0079370 A1
(43) Pub. Date: Mar. 6, 2025

(54) SEMICONDUCTOR DEVICE

(71) Applicant: Nuvoton Technology Corporation Japan, Kyoto (JP)

(72) Inventors: Shuichi OGATA, Osaka (JP); Hisashi KATADA, Kyoto (JP); Hiroaki YABU, Kyoto (JP); Katsumi OTANI, Osaka (JP)

(21) Appl. No.: 18/952,606

(22) Filed: Nov. 19, 2024

(30) Foreign Application Priority Data
May 25, 2022 (JP) 2022-085516

(51) Int. Cl. H01L 23/00; H01L 23/31; H01L 23/495; H01L 25/18

(52) U.S. Cl. CPC H01L 24/13; H01L 23/49513; H01L 23/49562; H01L 24/16; H01L 24/32; H01L 24/48; H01L 24/73; H01L 23/3121; H01L 25/18; H01L 2224/13005; H01L 2224/16145; H01L 2224/32145; H01L 2224/32245; H01L 2224/48245; H01L 2224/73204; H01L 2224/73207; H01L 2224/73215; H01L 2224/73253; H01L 2224/73265; H01L 2225/06513; H01L 2225/06568; H01L 2924/3511

(57) ABSTRACT

A semiconductor device includes: a first semiconductor chip mounted onto a die pad; a second semiconductor chip mounted face down onto the first semiconductor chip and including a band gap element. The first semiconductor chip and the second semiconductor chip are electrically bonded to each other by a bonding material. A filler is disposed between the first semiconductor chip and the second semiconductor chip. When the distance from the band gap element to the bonding material is defined as r1 and the distance from the band gap element to an outline side of the first semiconductor chip is defined as r2, r1/r2≥(−0.148×r1+0.021)×r2+(0.550×r1+0.020).

### CROSS REFERENCE TO RELATED APPLICATIONS

This is a continuation application of PCT International Application No. PCT/JP2023/018209 filed on May 16, 2023, designating the United States of America, which is based on and claims priority of Japanese Patent Application No. 2022-085516 filed on May 25, 2022. The entire disclosures of the above-identified applications, including the specifications, drawings and claims are incorporated herein by reference in their entirety.

### FIELD

The present disclosure relates to a semiconductor device and, in particular, to a technique suitable for the structure of a semiconductor device capable of mitigating the effects of a secular change in addition to suppressing initial stress and capable of reducing the variation range of a reference voltage generated by an internal reference voltage generation circuit.

### BACKGROUND

Regarding the structures of conventional semiconductor devices that suppress the effects of a stress change, in, for example, the full-mold semiconductor package disclosed in Patent Literature (PTL 1), semiconductor chips are stacked as three stacked layers mounted face up, thereby reducing compressive stress caused in a circuit provided in the middle chip due to the shrinkage of encapsulating resin. It should be noted that stress caused in a semiconductor chip includes not only initial stress caused due to the shrinkage of encapsulating resin that occurs when cooling the semiconductor chip to room temperature after the semiconductor chip is encapsulated with the high-temperature encapsulating resin in fabricating a semiconductor device, but also a stress change due to a secular change that occurs afterwards.

### CITATION LIST

### Patent Literature

PTL 1: Japanese Patent No. 6131875

### SUMMARY

### Technical Problem

In conventional semiconductor devices, stress is reduced by constituent components behaving in such a manner that they offset each other during the shrinkage of resin. However, it is extremely difficult to control the behaviors of the constituent components. It is not possible to follow a stress change caused by a secular change, and the stress change deteriorates the accuracy of a reference voltage generated by a reference voltage generation circuit formed in a semiconductor chip.

In view of the above, the present disclosure aims to provide a semiconductor device including a highly accurate, highly stable reference voltage generation circuit.

### Solution to Problem

In view of the above, a semiconductor device according to one aspect of the present disclosure includes: a lead frame in a planar shape; a first semiconductor chip mounted face up onto the lead frame; a second semiconductor chip mounted face down onto the first semiconductor chip, the second semiconductor chip being smaller in chip size than the first semiconductor chip and including a band gap element having a PN junction included in a band gap reference circuit as a reference voltage generation circuit; a bonding material electrically bonding the first semiconductor chip and the second semiconductor chip; and a filler disposed between the first semiconductor chip and the second semiconductor chip. In a plan view of the lead frame, when the distance from a first position where the band gap element is disposed to a second position that is the position of the bonding material closest to the band gap element is defined as r1, and the distance from the first position to an outline side of the first semiconductor chip closest to the first position is defined as r2, r1/r2≥(−0.148 ×r1+0.021)×r2+(0.550×r1+0.020).

### Advantageous Effects

The present disclosure provides a semiconductor device including a highly accurate, highly stable reference voltage generation circuit.

### BRIEF DESCRIPTION OF DRAWINGS

These and other advantages and features will become apparent from the following description thereof taken in conjunction with the accompanying Drawings, by way of non-limiting examples of embodiments disclosed herein.

FIG. 1 is a cross-sectional view illustrating a structure of a semiconductor device according to Embodiment 1.

FIG. 2 is a plan view and a cross-sectional view of the semiconductor device illustrated in FIG. 1.

FIG. 3 illustrates a plot of results calculated by simulating the relationship between the ratio of r1 to r2 and the stress when a filler<a bonding material in terms of the linear expansion coefficient in the semiconductor device illustrated in FIG. 1.

FIG. 4 illustrates a plot of results calculated by simulating the relationship between the ratio of r1 to r2 and the stress when the filler>the bonding material in terms of the linear expansion coefficient in the semiconductor device illustrated in FIG. 1.

FIG. 5 illustrates a plot of results calculated by simulating the relationship between the ratio of r1 to r2 and r2 for each size of a second semiconductor chip in the semiconductor device illustrated in FIG. 1.

FIG. 6 illustrates a plot of results calculated by simulating the relationship between the ratio of r1 to the height of the bonding material and the stress in the semiconductor device illustrated in FIG. 1.

FIG. 7 is a figure for explaining stress caused in a band gap element due to a difference in the linear expansion coefficient between the filler and the bonding material in the semiconductor device illustrated in FIG. 1.

FIG. 8 is an enlarged cross-sectional view illustrating the structure of the semiconductor device illustrated in FIG. 1.

FIG. 9 is a cross-sectional view illustrating a structure of a semiconductor device according to Embodiment 2.

### DESCRIPTION OF EMBODIMENTS

Hereinafter, embodiments of semiconductor devices according to the present disclosure are described with reference to the figures. Each of the embodiments described below shows a specific example of the present disclosure. The numerical values, shapes, materials, constituent elements, arrangement and connection of the constituent elements, steps, order of steps, and other details indicated in the embodiments described below are merely examples, and do not intend to limit the present disclosure. In addition, the figures are not necessarily precise illustrations. In the figures, substantially the same constituent elements are assigned the same reference sign, and overlapping explanations are omitted or simplified.

### Embodiment 1

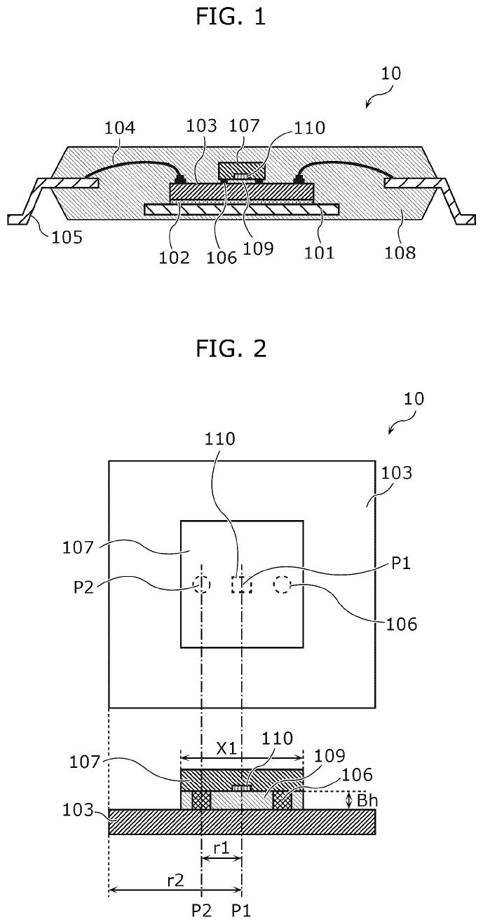

FIG. 1 is a cross-sectional view illustrating a structure of semiconductor device 10 according to Embodiment 1. In FIG. 1, semiconductor device 10 in the present disclosure includes die pad 101, paste material 102, first semiconductor chip 103, bonding wire 104, pin terminal 105, bonding material 106, second semiconductor chip 107, encapsulating resin 108, and filler 109. Die pad 101 and pin terminal 105 form a planar lead frame. Here, “planar” means not only a flat plate but also a flat plate having a stepwise portion provided with steps.

First semiconductor chip 103 is mounted face up to die pad 101 with paste material 102, and receives and outputs a signal from and to an external location via bonding wire 104 and pin terminal 105. Second semiconductor chip 107 is smaller in chip size than first semiconductor chip 103, and is mounted by flip chip mounting (that is, mounted face down) onto first semiconductor chip 103 with bonding material 106. Second semiconductor chip 107 is electrically bonded to first semiconductor chip 103 through bonding material 106, and receives and outputs a signal. It should be noted that second semiconductor chip 107 being smaller in chip size than first semiconductor chip 103 means a state in which a portion of first semiconductor chip 103 located below second semiconductor chip 107 is seen in a plan view of the lead frame.

In addition, filler 109 is disposed between first semiconductor chip 103 and second semiconductor chip 107. Furthermore, die pad 101, paste material 102, first semiconductor chip 103, bonding wire 104, pin terminal 105, bonding material 106, second semiconductor chip 107, and filler 109 are integrally molded with encapsulating resin 108 and form a package.

In addition, band gap element 110 has a PN junction included in a band gap reference circuit as a reference voltage generation circuit, is formed on the surface, where bonding material 106 is disposed, of second semiconductor chip 107, and is not in direct contact with encapsulating resin 108. Thus, band gap element 110 has a structure insusceptible to the effects of mitigation of mold shrinkage of encapsulating resin 108 and shrinkage force due to a secular change.

Next, the size relationship between second semiconductor chip 107 and first semiconductor chip 103 is described with reference to FIGS. 2 to 5.

To explain the relationship, the definitions of distance r1 and distance r2 are explained with reference to FIG. 2. FIG. 2 is a plan view and a cross-sectional view of semiconductor device 10 illustrated in FIG. 1. As illustrated in FIG. 2, in the plan view of the lead frame, the distance from first position P1 where band gap element 110 is disposed to second position P2 that is the position of bonding material 106 closest to band gap element 110 is defined as r1, and the distance from first position P1 to an outline side of first semiconductor chip 103 closest to first position P1 is defined as r2. FIG. 2 also illustrates size X1 (millimeter square) of second semiconductor chip 107 and height Bh of bonding material 106. It should be noted that the position of an object in the plan view of the lead frame means the central position of the object in the plan view. In addition, in the simulations described later, the outlines of first semiconductor chip 103 and second semiconductor chip 107 in the plan view are squares.

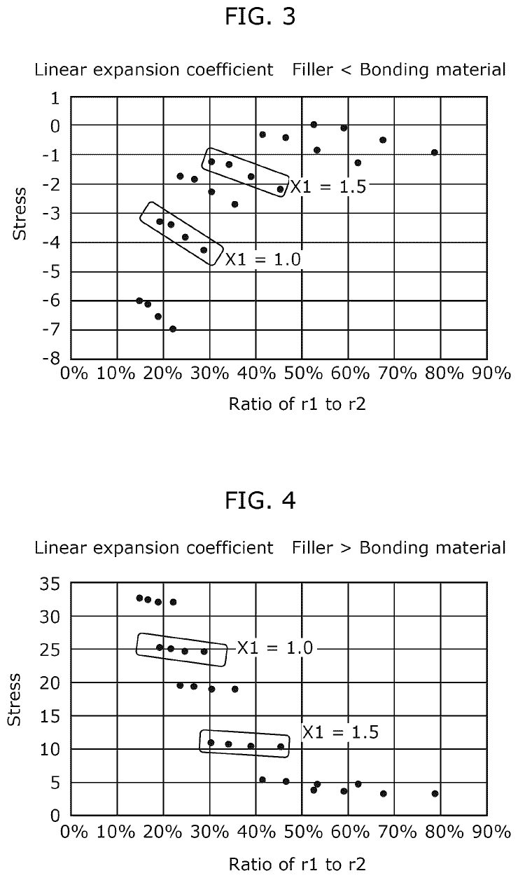

FIG. 3 illustrates a plot of results calculated by simulating the relationship between the ratio of r1 to r2 (the horizontal axis) and the stress (the vertical axis) caused in band gap element 110 when filler 109<bonding material 106 in terms of the linear expansion coefficient in semiconductor device 10 illustrated in FIG. 1. FIG. 4 illustrates a plot of results calculated by simulating the relationship between the ratio of r1 to r2 (the horizontal axis) and the stress (the vertical axis) caused in band gap element 110 when filler 109>bonding material 106 in terms of the linear expansion coefficient in semiconductor device 10 illustrated in FIG. 1.

In FIGS. 3 and 4, the stress indicated by the vertical axis is positive when the stress caused in band gap element 110 is tensile stress and negative when the stress is compressive stress. Thus, in FIG. 3, the compressive stress (negative stress) is plotted, and the compressive stress becomes larger toward the bottom of the vertical axis. Meanwhile, in FIG. 4, the tensile stress (positive stress) is plotted, and the tensile stress becomes larger toward the top of the vertical axis.

In addition, FIGS. 3 and 4 illustrate the plots of the results obtained by simulating while changing the size of first semiconductor chip 103 and size X1 of second semiconductor chip 107. The plot groups of X1=1.0 (1.0 millimeter square) and X1=1.5 (1.5 millimeter square), which are typical sizes of second semiconductor chip 107, are encircled by the lines.

From the above results, FIG. 3 illustrates the plot with a positive slope in general, and FIG. 4 illustrates the plot with a negative slope in general. As such, in either case, the ratio of r1 to r2 increases. That is, the stress tends to decrease with an increase in the distance from band gap element 110 to bonding material 106 relative to the distance from band gap element 110 to the outline side of first semiconductor chip 103.

Furthermore, as known from the position of the plot group of X1=1.0 and the position of the plot group of X1=1.5 in FIGS. 3 and 4, the stress tends to decrease with an increase in the size of first semiconductor chip 103.

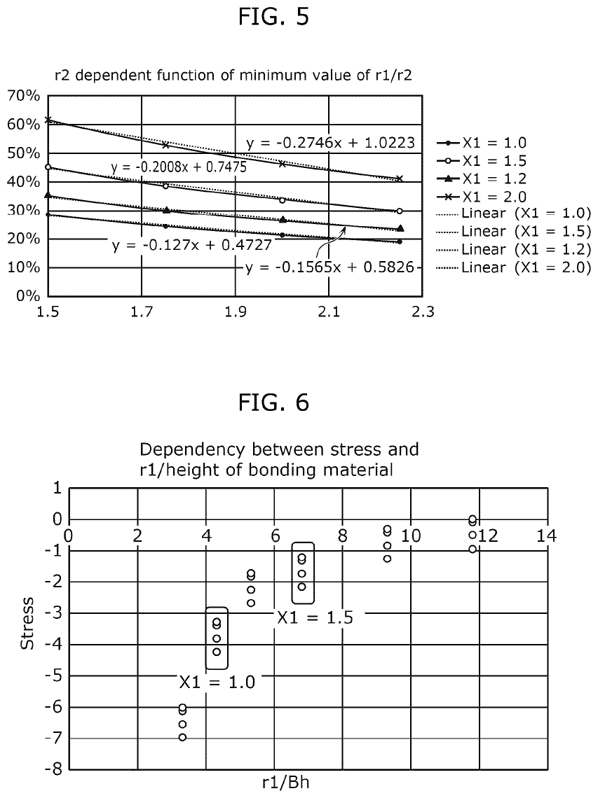

FIG. 5 illustrates a graph and function expressions in the graph, the graph illustrating results calculated by simulating relationships between the minimum value of the ratio of r1 to r2 (the vertical axis) and r2 (the horizontal axis) for each size X1 of second semiconductor chip 107 of semiconductor device 10 illustrated in FIG. 1. Here, for each of sizes X1 of second semiconductor chip 107 of 1.0, 1.5, 1.2, and 2.0, the minimum value of the vertical axis (the ratio of r1 to r2) is defined as y, and the value of the horizontal axis (r2) is defined as x. The plot curves (the continuous lines) and the straight lines (the dotted lines) of the linear approximate equations (y=ax+b) thereof are illustrated.

When r1 dependency of each of coefficient a and intercept b of each of the four linear approximate equations (y=ax+b) is calculated on the basis of the results, the following linear approximate equations (Expressions 1 and 2) are obtained.

$$a = - 0.1 \; 48 \times r 1 + 0.021 \qquad ( Expression 1 )$$

$$b = 0. 5 \; 50 \times r 1 + 0.02 \qquad ( Expression 2 )$$

From the above, the chip size dependency of the ratio of r1 to r2 can be expressed by the following function expression (Expression 3).

$$r 1 / r 2 \geq ( - 0.148 \times r 1 + 0.021 ) \times r 2 + ( 0.55 \times r 1 + 0.02 ) \qquad ( Expression 3 )$$

That is, by designing r1 and r2 that satisfy Expression 3 above, it is possible to bring the stress caused in band gap element 110 closer to the minimum value.

It should be noted that Expression 3 above may be expressed as Expression 3-1 below by decreasing the number of significant digits of coefficient a and intercept b by one.

$$r 1 / r 2 \geq ( - 0.15 \times r 1 + 0.02 ) \times r 2 + ( 0.55 \times r 1 + 0 \text{.02} ) \qquad ( Expression 3 - 1 )$$

In semiconductor device 10, bonding material 106 serves as the fulcrum, and band gap element 110 serves as the point of action. When the entire package is warped during heating, the end of first semiconductor chip 103 serves as the fulcrum, and bonding material 106 serves as the point of action. Furthermore, the stress value changes also due to the effects of the behavior of filler 109 between first semiconductor chip 103 and second semiconductor chip 107. Thus, increasing the distances from the fulcrums to the points of action makes the stress due to the warping of the entire package less likely to propagate and makes it easier to follow the behavior of filler 109.

As described above, in semiconductor device 10 according to Embodiment 1, second semiconductor chip 107, which includes the band gap reference circuit as the reference voltage generation circuit, is mounted face down onto first semiconductor chip 103. Thus, band gap element 110 having the PN junction included in the band gap reference circuit included in second semiconductor chip 107 is not in direct contact with encapsulating resin 108. For this reason, band gap element 110 is insusceptible to the effects of the shrinkage of encapsulating resin 108, which can suppress the initial stress and mitigate the stress change caused due to the secular change.

Thus, in semiconductor device 10 according to Embodiment 1, the reference voltage generation circuit for which high accuracy and stability are required is formed in second semiconductor chip 107, and second semiconductor chip 107 is mounted face down onto first semiconductor chip 103. The above structure makes it possible to suppress the initial stress caused due to the temperature change and mitigate the stress change caused due to the secular change. Accordingly, it is possible to decrease the variation range of the accuracy of a reference voltage generated by the reference voltage generation circuit.

When size X1 of second semiconductor chip 107 is set to the range of 1.0 mm to 1.5 mm, coefficient a and intercept b of each linear approximate equation (y=ax+b) in FIG. 5 can be approximated by the following values.

$$a = - 0.127 \qquad ( Expression 4 )$$

$$b = 0.458 \qquad ( Expression 5 )$$

As a result, Expression 3 above can be expressed as Expression 6 below.

$$r 1 / r 2 \geq - 0.1 \; 27 \times r 2 + 0.458 \qquad ( Expression 6 )$$

Thus, when size X1 of second semiconductor chip 107 is in the range of 1.0 mm to 1.5 mm, by setting r1 and r2 that enable establishment of Expression 6 above, it is possible to bring the stress value applied to band gap element 110 closer to the minimum value.

It should be noted that Expression 6 above may be expressed as Expression 6-1 below by decreasing the number of significant digits of coefficient a and intercept b by one.

$$r 1 / r 2 \geq - 0.13 \times r 2 + 0.46 \qquad ( Expression 6 - 1 )$$

In addition, when size X1 of second semiconductor chip 107 is set to be larger than 1.5 mm, coefficient a and intercept b of each linear approximate equation (y=ax+b) in FIG. 5 can be approximated by the following values.

$$a = - 0.201 \qquad ( Expression 7 )$$

$$b = 0.740 \qquad ( Expression 8 )$$

As a result, Expression 3 above can be expressed as Expression 9 below.

$$r 1 / r 2 \geq - 0.2 \; 01 \times r 2 + 0.740 \qquad ( Expression 9 )$$

Thus, when size X1 of second semiconductor chip 107 is larger than 1.5 mm, by setting r1 and r2 that enable establishment of Expression 9 above, it is possible to bring the stress value applied to band gap element 110 closer to the minimum value.

It should be noted that Expression 9 above may be expressed as Expression 9-1 by decreasing the number of significant digits of coefficient a and intercept b by one.

$$r 1 / r 2 \geq - 0.20 \times r 2 + 0.74 \qquad ( Expression 9 - 1 )$$

FIG. 6 illustrates a plot of results calculated by simulating the relationship between the ratio of r1 to height Bh of bonding material 106 (r1/Bh: the horizontal axis) and the stress (the vertical axis) in semiconductor device 10 illustrated in FIG. 1. As in the case of FIGS. 3 and 4, FIG. 6 illustrates the plot of the results obtained by simulating while changing the size of first semiconductor chip 103 and size X1 of second semiconductor chip 107. The plot groups of X1=1.0 (1.0 millimeter square) and X1=1.5 (1.5 millimeter square), which are typical sizes of second semiconductor chip 107, are encircled by the lines.

The results show the following: in semiconductor device 10 according to Embodiment 1, when size X1 of second semiconductor chip 107 is set to the range of 1.0 mm to 1.5 mm, as it is understood from FIG. 6 that r1/Bh 4.30, by setting height Bh of bonding material 106 to cause the ratio (r1/Bh) to be at least 4.30, it is possible to bring the stress value applied to band gap element 110 closer to the minimum value.

In addition, in FIG. 6, when size X1 of second semiconductor chip 107 is set to be larger than 1.5 mm, as it is understood from FIG. 6 that r1/Bh>6.80 is established, by setting the height of bonding material 106 to cause the ratio (r1/Bh) to be at least 6.80, it is possible to bring the stress value applied to band gap element 110 closer to the minimum value.

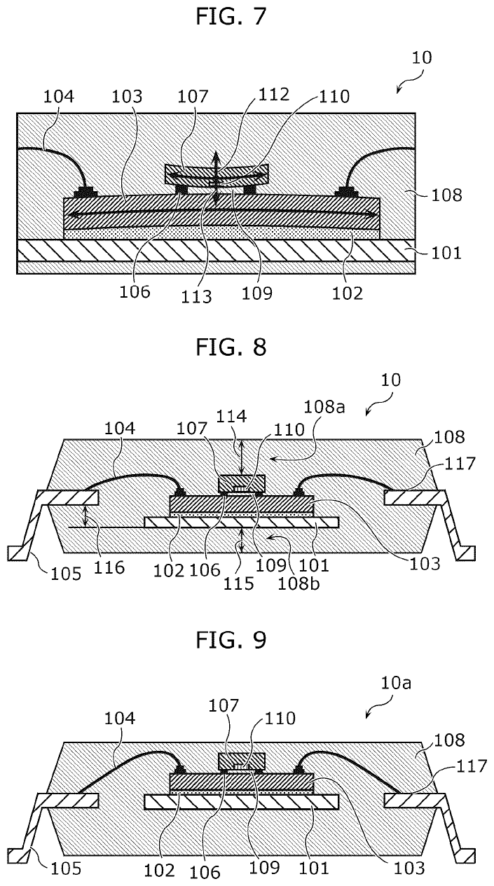

FIG. 7 is a figure for explaining the stress caused in band gap element 110 due to a difference in the linear expansion coefficient between filler 109 and bonding material 106 in semiconductor device 10 illustrated in FIG. 1. Arrow 112 indicates the direction of the external force that causes compressive stress in band gap element 110, and arrow 113 indicates the direction of the external force that causes tensile stress in band gap element 110.

FIG. 8 is an enlarged cross-sectional view illustrating the structure of semiconductor device 10 illustrated in FIG. 1. Encapsulating resin 108 above second semiconductor chip 107 is referred to as upper resin layer 108a, and encapsulating resin 108 below die pad 101 is referred to as lower resin layer 108b. In addition, inner lead 117 is included in the lead frame and is a terminal connected to first semiconductor chip 103 with bonding wire 104. The height of the bottom surface position of inner lead 117 from the bottom surface position of die pad 101 is referred to as depress 116.

In semiconductor device 10 according to Embodiment 1, when the linear expansion coefficient of filler 109 is smaller than that of bonding material 106 (case 1), bonding material 106 shrinks more than filler 109 when encapsulating resin 108 is cooled from a high temperature. Thus, as indicated by arrow 112 in FIG. 7, the force that causes compressive stress in band gap element 110 works due to the shrinkage of bonding material 106 and the deformation of first semiconductor chip 103. For instance, in case 1, filler 109 is epoxy resin, and bonding material 106 is SnAg-based solder.

Thus, to make the structure above filler 109 flexible in order to disperse the stress from above and make the structure below filler 109 rigid in order to avoid propagating the stress from below, the thicknesses of first semiconductor chip 103 and second semiconductor chip 107, the bottom surface position of die pad 101, that is, the amount of depress, the thickness of the lead frame, thickness 115 of lower resin layer 108b, and thickness 114 of upper resin layer 108a are set to predetermined numerical values. By doing so, it is possible to mitigate the compressive stress caused in band gap element 110.

As one of the settings, by making second semiconductor chip 107 thinner than first semiconductor chip 103, for example, setting the thickness of first semiconductor chip 103 to 0.25 mm and the thickness of second semiconductor chip 107 to 0.25 mm or less, it is possible to mitigate the compressive stress caused in band gap element 110.

In addition, as another setting, by processing the lead frame so that the amount of depress is, for example, 0.10 mm or less, it is possible to mitigate the compressive stress caused in band gap element 110.

In addition, as still another setting, by setting the thickness of the lead frame to 0.6 times the thickness of first semiconductor chip 103, for example, at most 0.15 mm, it is possible to mitigate the compressive stress caused in band gap element 110.

In addition, as still another setting, by setting thickness 115 of lower resin layer 108b to twice the thickness of first semiconductor chip 103, for example, at least 0.525 mm, it is possible to mitigate the compressive stress caused in band gap element 110.

In addition, as still another setting, by making thickness 114 of upper resin layer 108a less than the thickness of second semiconductor chip 107, for example, setting thickness 114 to at most 0.105 mm, it is possible to mitigate the compressive stress caused in band gap element 110.

In addition, contrary to case 1 described above, when the linear expansion coefficient of filler 109 is larger than that of bonding material 106 (case 2), filler 109 shrinks more than bonding material 106 when encapsulating resin 108 is cooled from a high temperature. Thus, as indicated by arrow 113 in FIG. 7, the force that causes tensile stress in band gap element 110 works due to the shrinkage of filler 109. For instance, in case 2, bonding material 106 is SnAg-based solder, and filler 109 is an underfill material.

Thus, contrary to case 1 described above, to make the structure below filler 109 flexible in order to disperse the stress from below and make the structure above filler 109 flexible in order to deal with the stress from above, the thicknesses of first semiconductor chip 103 and second semiconductor chip 107, the bottom surface position of die pad 101, that is, the amount of depress, the thickness of the lead frame, thickness 115 of lower resin layer 108b, and thickness 114 of upper resin layer 108a are set to predetermined numerical values. By doing so, it is possible to mitigate the tensile stress caused in band gap element 110.

As one of the settings, by making first semiconductor chip 103 thinner than second semiconductor chip 107, for example, setting the thickness of first semiconductor chip 103 to 0.15 mm and the thickness of second semiconductor chip 107 to 0.25 mm, it is possible to mitigate the tensile stress caused in band gap element 110.

In addition, as another setting, by processing the lead frame so that the amount of depress is 0.10 mm or more, it is possible to mitigate the tensile stress caused in band gap element 110.

In addition, as still another setting, by setting the thickness of the lead frame to at least the thickness of first semiconductor chip 103, for example, at least 0.15 mm, it is possible to mitigate the tensile stress caused in band gap element 110.

In addition, as still another setting, by setting thickness 115 of lower resin layer 108b to three times the thickness of first semiconductor chip 103, for example, at most 0.425 mm, it is possible to mitigate the tensile stress caused in band gap element 110.

In addition, as still another setting, by making thickness 114 of upper resin layer 108a more than the thickness of second semiconductor chip 107, for example, setting thickness 114 to at least 0.255 mm, it is possible to mitigate the tensile stress caused in band gap element 110.

In addition, as still another setting, the height of bonding material 106 is set to a low height such as a height of 0.10 mm or less, thereby decreasing the volume of filler 109. This makes it possible to decrease the tensile stress caused in band gap element 110.

In addition, as still another setting, by using, for example, solder with a low linear expansion coefficient as bonding material 106, bonding material 106 follows the tensile stress caused due to the shrinkage of filler 109, which can mitigate the tensile stress caused in band gap element 110.

It should be noted that in semiconductor device 10 according to Embodiment 1, in the plan view of the lead frame, a space not filled with filler 109 may be present at first position P1 where band gap element 110 is disposed. For instance, as the basic structure, semiconductor device 10 described in Embodiment 1 may be a semiconductor device in which filler 109 is not present, that is, a space is present between filler 109 and the surface of second semiconductor chip 107, especially the surface where band gap element 110 is present. Band gap element 110 is not in contact with the other materials because of the presence of the space, which provides the structure in which band gap element 110 is insusceptible to the warping behavior of the package due to the shrinkage during the temperature change of the resin encapsulated to cover first semiconductor chip 103 and second semiconductor chip 107 and insusceptible to the shrinkage of bonding material 106 and filler 109. Accordingly, band gap element 110 is placed in a stress-free state.

It should be noted that in semiconductor device 10 according to Embodiment 1, in the plan view of the lead frame, first position P1, where band gap element 110 is disposed, has equal distances to both ends of one side of the outline of second semiconductor chip 107. It should be noted that when the outline of second semiconductor chip 107 in the plan view is rectangular, first position P1 has equal distances to both ends of a short side of the outline of second semiconductor chip 107.

Thus, in second semiconductor chip 107, a central part of the chip has the smallest value in terms of the stress plane distribution. Thus, by disposing band gap element 110 in the center, it is also possible to suppress a change in the reference voltage generated by reference voltage generation circuit, due to the initial stress and secular change.

In addition, in the plan view of the lead frame, the center point of second semiconductor chip 107 overlaps the center point of the lead frame. Thus, the deformation of band gap element 110 is also decreased by disposing second semiconductor chip 107 in the center where the stress is smallest in the entire package, which can also suppress a change in the measurement accuracy due to the initial stress and secular change.

### Embodiment 2

FIG. 9 is a cross-sectional view illustrating a structure of semiconductor device 10a according to Embodiment 2.

Semiconductor device 10a according to Embodiment 2 is the same as semiconductor device 10 according to Embodiment 1 in terms of the composition of materials used and the structure in which second semiconductor chip 107 is mounted face down to first semiconductor chip 103. However, in the cross-sectional structure, the bottom surface position of die pad 101 is at or above the height of the bottom surface of inner lead 117. It should be noted that in Embodiment 2, the linear expansion coefficient of filler 109 is smaller than that of bonding material 106.

With such a structure, in semiconductor device 10a according to Embodiment 2, the volumes of an upper resin portion and a lower resin portion are asymmetrical. Thus, the shrinkage of the lower chip and the portion therebelow offsets stress caused in the upper chip due to resin shrinkage, which can make the stress value applied to band gap element 110 the minimum value.

Although the semiconductor devices according to the present disclosure are described above on the basis of Embodiments 1 and 2, the present disclosure is not limited to the embodiments. The present disclosure includes, within the scope of the present disclosure, embodiment(s) obtained by making various changes envisioned by those skilled in the art to the embodiments and another embodiment obtained by combining some of the structural elements described in the embodiments.

For instance, in Embodiments 1 and 2, the cases in which filler 109 and bonding material 106 have different linear expansion coefficients are described. However, it is not essential that filler 109 and bonding material 106 have different linear expansion coefficients. Filler 109 and bonding material 106 may have similar linear expansion coefficients.

In addition, in Embodiments 1 and 2, at the first position in the plan view of the lead frame, a space not filled with filler 109 may be present between the surface of second semiconductor chip 107 and filler 109. However, filler 109 need not be disposed between first semiconductor chip 103 and second semiconductor chip 107.

In addition, in the simulations described in Embodiments 1 and 2, the outlines of first semiconductor chip 103 and second semiconductor chip 107 in the plan view are square. However, this is to simplify the calculation, and in the semiconductor devices in the present disclosure, the outlines of first semiconductor chip 103 and second semiconductor chip 107 in the plan view may be rectangular.

Although only some exemplary embodiments of the present disclosure have been described in detail above, those skilled in the art will readily appreciate that many modifications are possible in the exemplary embodiments without materially departing from the novel teachings and advantages of the present disclosure. Accordingly, all such modifications are intended to be included within the scope of the present disclosure.

1. A semiconductor device comprising:
a lead frame in a planar shape;
a first semiconductor chip mounted face up onto the lead frame;
a second semiconductor chip mounted face down onto the first semiconductor chip, the second semiconductor chip being smaller in chip size than the first semiconductor chip and including a band gap element having a PN junction included in a band gap reference circuit as a reference voltage generation circuit;
a bonding material electrically bonding the first semiconductor chip and the second semiconductor chip; and
a filler disposed between the first semiconductor chip and the second semiconductor chip, wherein
in a plan view of the lead frame, when a distance from a first position where the band gap element is disposed to a second position that is a position of the bonding material closest to the band gap element is defined as r1, and a distance from the first position to an outline side of the first semiconductor chip closest to the first position is defined as r2,
r1/r2≥(−0.148×r1+0.021)×r2+(0.550×r1+0.020).

2. The semiconductor device according to claim 1, wherein
r1/r2≤−0.127×r2+0.458.

3. The semiconductor device according to claim 2, wherein
r1/r2≤−0.201×r2+0.740.

4. The semiconductor device according to claim 1, wherein when a height of the bonding material is defined as Bh,
r1/Bh≥4.30.

5. The semiconductor device according to claim 4, wherein
r1/Bh≥6.80.

6. The semiconductor device according to claim 1, wherein
a linear expansion coefficient of the filler is smaller than a linear expansion coefficient of the bonding material, and
a thickness of the first semiconductor chip is more than a thickness of the second semiconductor chip.

7. The semiconductor device according to claim 6, wherein
the lead frame includes a die pad for disposing the first semiconductor chip, and an inner lead connected to the first semiconductor chip with a wire, and
a height of a bottom surface position of the inner lead from a bottom surface position of the die pad is 0.10 mm or less.

8. The semiconductor device according to claim 6, wherein
a thickness of the lead frame is less than 0.6 times the thickness of the first semiconductor chip.

9. The semiconductor device according to claim 6, further comprising:
a lower resin layer below the lead frame, wherein
a thickness of the lower resin layer is more than twice the thickness of the first semiconductor chip.

10. The semiconductor device according to claim 6, further comprising:
an upper resin layer above the second semiconductor chip, wherein
a thickness of the upper resin layer is less than the thickness of the second semiconductor chip.

11. The semiconductor device according to claim 1, wherein
a linear expansion coefficient of the filler is larger than a linear expansion coefficient of the bonding material, and
a thickness of the first semiconductor chip is less than a thickness of the second semiconductor chip.

12. The semiconductor device according to claim 11, wherein
the lead frame includes a die pad for disposing the first semiconductor chip, and an inner lead connected to the first semiconductor chip with a wire, and
a height of a bottom surface position of the inner lead from a bottom surface position of the die pad is 0.10 mm or more.

13. The semiconductor device according to claim 11, wherein
a thickness of the lead frame is more than the thickness of the first semiconductor chip.

14. The semiconductor device according to claim 11, further comprising:
a lower resin layer below the lead frame, wherein
a thickness of the lower resin layer is less than three times the thickness of the first semiconductor chip.

15. The semiconductor device according to claim 11, further comprising:
an upper resin layer above the second semiconductor chip, wherein
a thickness of the upper resin layer is more than the thickness of the second semiconductor chip.

16. The semiconductor device according to claim 11, wherein
a height of the bonding material is 0.10 mm or less.

17. The semiconductor device according to claim 11, wherein
the bonding material is solder.

18. The semiconductor device according to claim 1, wherein
at the first position in the plan view, a space not filled with the filler is present between a surface of the second semiconductor chip and the filler.

19. The semiconductor device according to claim 1, wherein
in the plan view, the first position has equal distances to both ends of one side of an outline of the second semiconductor chip.

20. The semiconductor device according to claim 1, wherein
in the plan view, a center point of the second semiconductor chip overlaps a center point of the lead frame.

21. A semiconductor device comprising:
a lead frame in a planar shape;
a first semiconductor chip mounted face up onto the lead frame;
a second semiconductor chip mounted face down onto the first semiconductor chip, the second semiconductor chip being smaller in chip size than the first semiconductor chip and including a band gap element having a PN junction included in a band gap reference circuit;
a bonding material electrically bonding the first semiconductor chip and the second semiconductor chip; and
a filler disposed between the first semiconductor chip and the second semiconductor chip, wherein
the lead frame includes a die pad for disposing the second semiconductor chip, and an inner lead connected to the first semiconductor chip with a wire,
a linear expansion coefficient of the filler is smaller than a linear expansion coefficient of the bonding material, and
a bottom surface position of the die pad is at or above a height of a bottom surface position of the inner lead.
